(19) United States
(12) Patent Application Publication
(10) Pub. No.: US 2006/0009017 A1
(43) Pub. Date: Jan. 12, 2006

(54) Method of crystallizing semiconductor film and method of manufacturing display device

(76) Inventors: Shigeru Sembommatsu, Chiba-shi (JP); Shuhei Yamamoto, Chiba-shi (JP); Mitsuru Suginoya, Chiba-shi (JP); Hideki Matsumura, Ishikawa (JP); Atsushi Masuda, Ishikawa (JP)

Correspondence Address: BRUCE L. ADAMS, ESQ.;31ST FLOOR, 50 BROADWAY, NEW YORK, NY, 10004, US

(21) Appl. No.: 11/155,959

(22) Filed: Jun. 17, 2005

(30) Foreign Application Priority Data
Jul. 8, 2004 (JP) 2004-201382

(51) Int. Cl. C23C 16/24; H01L 21/20; H01L 21/36

(52) U.S. Cl. 438/488

(57) ABSTRACT

Conventional methods of crystallizing a semiconductor film through scanning with a pulse laser have had a problem in that variation in particle diameter or shape of a crystal grain causes variation in characteristics of a thin film transistor, which lowers display quality of a liquid crystal display. In view of this, in a method of crystallizing a semiconductor film according to the present invention, after a step of performing scanning with a first pulse laser, scanning with a second pulse laser, which has a higher energy density than that of the first pulse laser, is performed in a substantially orthogonal direction to a traveling direction of scanning with the first pulse laser. With this method, the semiconductor film can be crystallized uniformly.

### BACKGROUND OF THE INVENTION

1. Field of the Invention

The present invention relates to a method of crystallizing a silicon film for a thin film transistor and a method of manufacturing a display device such as a liquid crystal display or an organic EL display which uses the method, and more particularly to a method of crystallizing a uniform polysilicon film for obtaining a thin film transistor having a uniform characteristic in a substrate surface.

2. Description of the Related Art

As a conventional method of crystallizing a silicon film for a thin film transistor, a method is generally known in which an amorphous silicon film formed on a glass substrate is subjected to a dehydrogenizing process through annealing at a high temperature of approximately 600° C. for several hours, and then the resultant amorphous silicon film is subjected to (irradiation) scanning with a line-beam shape pulse laser in one direction to be crystallized. The method is disclosed in, for example, a non-patent document, Technical Report of Japan Steel Works, Ltd. No. 54 (1998.8) “Crystallization of Amorphous Silicon with Excimer Laser Annealing Method”. Further, it is proposed in JP 2002-64060 A (Patent Document 1) that a dehydrogenizing process through pulse laser irradiation is used as a means that substitutes for a high-temperature dehydrogenizing process having a load applied thereto. Alternatively, a method of crystallizing a uniform amorphous silicon film is proposed in which an amorphous silicon film is subjected to scanning twice with a line-beam shape pulse laser in mutually orthogonal directions. That is, in JP 10-199808 A (Patent Document 2), a method of obtaining a uniform polysilicon film is proposed in which an amorphous silicon thin film, which has undergone a dehydrogenizing process, is crystallized through the first-time pulse laser scanning, and the resultant film is then re-melted and re-crystallized through the second-time pulse laser scanning in an orthogonal direction to the direction of the first-time pulse laser scanning.

For the sake of reduction in cost of a liquid crystal display, it has been generally performed that a pixel region and a peripheral circuit region are provided on a glass substrate and a pixel and a peripheral circuit are parallelly formed in these regions. At this time, there has been a problem in that variation in particle diameter or shape of a crystal grain of a polysilicon film causes variation in characteristics of a thin film transistor used for the pixel and peripheral circuit, which resultingly lowers the display quality of the liquid crystal display. That is, in the method, as in the non-patent document in the prior art, an amorphous silicon film is crystallized through (irradiation) scanning with a line-beam shape pulse laser in one direction to obtain a polysilicon film. A hysteresis in a scanning direction affects the crystal grain or shape of the polysilicon crystal because of variation in energy density of the pulse laser, step, and feed. That is, regularity of crystal grains in a stripe form is generated in the orthogonal direction to the scanning direction of the line beam. Because of the regularity, there is a defect that the thin film transistor characteristic depend on a channel forming direction. Further, for the purpose of obtaining a satisfactory polysilicon film, a pulse laser with a relatively high energy density of approximately 280 mj/cm² or more needs to be irradiated. Since hydrogen bumping, which is caused through irradiation with the pulse laser with a high energy density, roughens a surface of the polysilicon film, hydrogen contained in the amorphous silicon film needs to be reduced before the irradiation. In order to attain this, the film needs to be left in a high temperature atmosphere at approximately 600° C. for several hours to reduce a hydrogen content thereof. The dehydrogenizing process requires temperature rise (several hours)—leaving (several hours)—temperature lowering (several hours) because the film is left in the high temperature atmosphere. Thus, there is a load in terms of the process because of an increase of a tact time. As a method of reducing the load in terms of the process, a dehydrogenizing process through pulse laser irradiation has been also proposed, however, the above-mentioned variation in thin film transistor characteristic is not improved with this method. Further, the amorphous silicon film described in Patent Document 1 is deposited by plasma CVD with a silane gas as its main material. Thus, the hydrogen content in the film is approximately 10 Atomic % to 20 Atomic %. Therefore, the conditions such as the energy density, step, and feed, which are most suitable as the conditions for the dehydrogenizing process through pulse laser irradiation, have been difficult to be set. That is, there has been a problem in that, when the energy given to the amorphous silicon film from the pulse laser for dehydrogenization is too large, bumping occurs, on the other hand, when the energy is too small, hydrogen in the amorphous silicon film is not sufficiently reduced. Further, in the method as described in Patent Document 2 in which an amorphous silicon thin film, which has undergone a dehydrogenizing process, is crystallized through the first-time pulse laser scanning, the resultant film is then re-melted and re-crystallized through the second-time pulse laser scanning in an orthogonal direction to the direction of the first-time pulse laser scanning, and thus a uniform polysilicon film is obtained, there has been the following problem. That is, the polysilicon film with high crystallinity, which has been crystallized through the first-time pulse laser scanning, is harder to be subjected to a uniform re-melting process than the amorphous silicon film due to the influence of the size and shape of its crystal grain. As a result, the polysilicon film having uniform crystal grains and shape is hard to be obtained in a recrystallization process.

### SUMMARY OF THE INVENTION

The present invention has been made in view of the above, and provides a method of crystallizing a silicon film for a thin film transistor used in a liquid crystal display, and has an object to provide a method of crystallizing a uniform polysilicon film for obtaining a thin film transistor having a uniform characteristic in a substrate surface.

According to the present invention, there is provided a method of crystallizing a semiconductor film in which a semiconductor film is formed into a polycrystalline semiconductor film through scanning with pulse lasers, including steps of: scanning a semiconductor film with a first pulse laser; and scanning the semiconductor film with a second pulse laser in a substantially orthogonal direction to a scanning direction of the first pulse laser, in which an energy density of the first pulse laser is lower than that of the second pulse laser.

Here, the first pulse laser has an energy density that does not completely melt the semiconductor film. Further, the semiconductor film is formed by a catalytic CVD method. Further, in the step of scanning the semiconductor film with the first pulse laser, dehydrogenization of the semiconductor film is performed. Here, the semiconductor film is a film which is mainly formed of silicon. More specifically, the semiconductor film is composed of an amorphous silicon thin film with a hydrogen content of 7 Atomic % or less.

Further, the second pulse laser provides a line beam having a long side in a perpendicular direction to a scanning traveling direction thereof and an overlap ratio of 70% or more, and a pulse energy per time which ranges from 280 mj/cm² to 380 mj/cm². Further, the first pulse laser provides a line beam having a long side in a perpendicular direction to a scanning traveling direction thereof and an overlap ratio of 70% or more, and a difference in energy between the first pulse laser and the second pulse laser is 150 mj/cm² or less.

Furthermore, a method of manufacturing a display device according to the present invention includes steps of: scanning a semiconductor film formed on a first substrate with a first pulse laser; scanning the semiconductor film with a second pulse laser in a substantially orthogonal direction to the scanning direction of the first pulse laser; forming a thin film transistor with the use of the semiconductor film thus formed; and forming a display element with the use of the first substrate, in which an energy density of the first pulse laser is lower than that of the second pulse laser.

### BRIEF DESCRIPTION OF THE DRAWINGS

In the accompanying drawings:

FIGS. 1A and 1B are schematic diagrams for explaining a method of crystallizing a semiconductor film according to the present invention;

FIGS. 2A and 2B are schematic diagrams for explaining the method of crystallizing a semiconductor film according to the present invention;

FIG. 3 is a schematic diagram for explaining a method of depositing a semiconductor film used in the present invention;

FIG. 4 is a schematic diagram showing a sectional structure of a thin film transistor according to the present invention; and

FIG. 5 is a schematic diagram showing a catalyst used in the present invention.

### DETAILED DESCRIPTION OF THE PREFERRED EMBODIMENTS

According to the present invention, there is provided a crystallization method in which a semiconductor film is formed into a polycrystalline semiconductor film through scanning with pulse lasers. The method includes steps of: scanning a semiconductor film formed on an insulating substrate with a first pulse laser; and scanning the semiconductor film with a second pulse laser in a substantially orthogonal direction to a scanning direction of the first pulse laser, and is characterized in that an energy density of the first pulse laser is lower than that of the second pulse laser. With such a crystallization method, a semiconductor film is obtained in which uniform crystallization is realized in a substrate surface. Thus, the characteristics of a thin film transistor, in which the crystallized semiconductor film is used, becomes uniform. Therefore, a thin film transistor liquid crystal display or an organic EL display can be produced stably without deterioration of its display quality.

Further, it is adopted that the first pulse laser has an energy density that does not completely melt the semiconductor film. As a result, the process from remelting to recrystallization through the second laser scanning becomes more uniform.

Further, a semiconductor film, which is mainly formed of silicon with a low hydrogen content, is formed by a catalytic CVD method. Thus, the setting width of the irradiation conditions of laser scanning for performing a dehydrogenizing process to the semiconductor film with the first laser scanning is expanded. Therefore, a wide spectrum of combinations of the first laser scanning irradiation conditions and the second laser scanning irradiation conditions are enabled. Resultingly, the laser scanning irradiation conditions for stably obtaining uniform crystals of the semiconductor film, which is mainly formed of silicon, can be set.

Moreover, a method of manufacturing a display device of the present invention includes the steps of: scanning a semiconductor film formed on a first substrate with a first pulse laser; scanning the semiconductor film with a second pulse laser with an energy density higher than that of the first pulse laser in a substantially orthogonal direction to a scanning direction of the first pulse laser; forming a thin film transistor with the use of the semiconductor film thus formed; and forming a display element with the use of the first substrate.

In the case of, for example, a liquid crystal display device as the display device in the manufacturing method, the method includes the steps of: scanning a semiconductor film formed on a first substrate with a first pulse laser; scanning the semiconductor film with a second pulse laser with an energy density higher than that of the first pulse laser in a substantially orthogonal direction to a scanning direction of the first pulse laser; forming a thin film transistor with the use of the semiconductor film thus formed; providing a pixel electrode that connects with an electrode of the thin film transistor; forming an opposing electrode on a second substrate; and providing a liquid crystal layer in a gap between the first substrate and the second substrate. Furthermore, in the case of, for example, an EL display device as the display device in the manufacturing method, the method includes the steps of: scanning a semiconductor film formed on a first substrate with a first pulse laser; scanning the semiconductor film with a second pulse laser with an energy density higher than that of the first pulse laser in a substantially orthogonal direction to the scanning direction of the first pulse laser; forming a thin film transistor with the use of the semiconductor film thus formed; providing a pixel electrode that connects with an electrode of the thin film transistor; providing an EL layer on the first substrate having the pixel electrode formed thereon; and forming a second electrode on the EL layer.

Hereinafter, description will be made of embodiments of the present invention with reference to the accompanying drawings.

### Embodiment 1

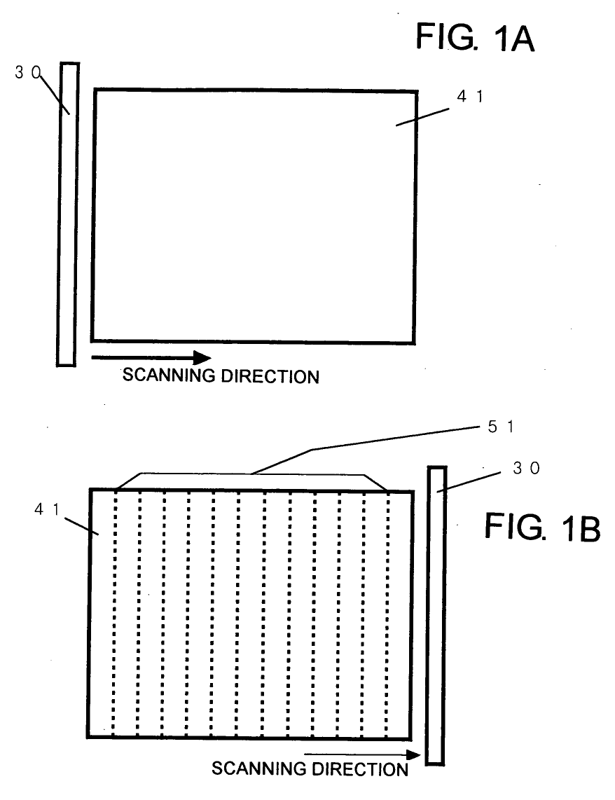

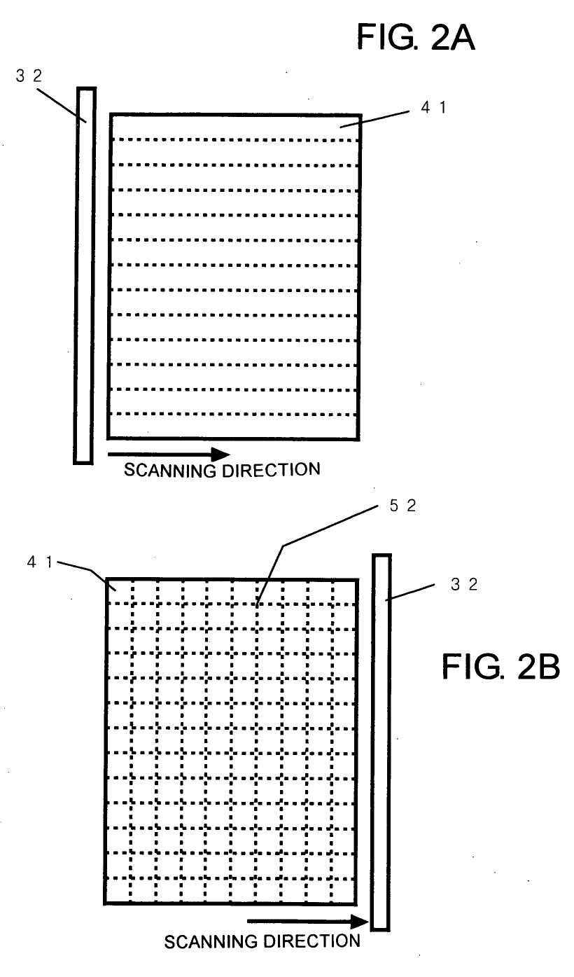

An embodiment of a method of crystallizing a semiconductor film of the present invention will be described in detail with reference to FIGS. 1A and 1B and FIGS. 2A and 2B. Here, an example is described in which a glass substrate 41 with dimensions of 370 cm×470 cm×0.7 mmt is used as an insulating substrate. An amorphous silicon film with a thickness of 500 Å as a semiconductor film was deposited on the glass substrate by a known plasma CVD method with SiH₄ and H₂ as material gases. Then, the amorphous silicon film was subjected to a dehydrogenizing process in a nitrogen atmosphere at 600° C. for 5 hours. An explanation will be made of a first step of scanning the semiconductor film on the glass substrate with a first pulse laser. As shown in FIG. 1A, a first pulse laser 30 has a long side in an orthogonal direction to a scanning direction, and is composed of an optical system such that the long side has a length not less than the width of the short side (370 cm) of the glass substrate 41. FIG. 1B schematically shows a state in which the amorphous silicon film on the glass substrate 41 has been scanned with the first pulse laser 30. Here, an excimer laser with: dimensions of 400 cm in length×180 μm in width; an energy density of 230 mj/cm²; and a pulse frequency of 300 Hz was used as the first pulse laser 30, and the amorphous silicon film on the glass substrate 41 was scanned with a laser source at an overlap ratio of 93% to be irradiated. Thereafter, the amorphous silicon film on the glass substrate 41 was observed by means of an interatomic force microscope (hereinafter, referred to as AFM) and a scanning electron microscope (hereinafter, referred to as SEM). As a result, an optical irradiation hysteresis 51 with a constant interval was found in the orthogonal direction to the scanning direction of the first pulse laser 30. The irradiation hysteresis 51 depends on irradiation conditions of the laser. In the case of this embodiment, the interval was approximately 0.2 μm.

Next, an explanation will be made of a step of performing scanning with a second pulse laser. As shown in FIG. 2A, a second pulse laser 32 has a long side in an orthogonal direction to a scanning direction, and is composed of an optical system such that the long side has a length not less than of the width of the long side (470 cm) of the glass substrate 41. Here, an excimer laser with: dimensions of 500 cm in length×180 μm in width; an energy density of 350 mj/cm₂; and a pulse frequency of 300 Hz was used as the second pulse laser 32, and the amorphous silicon film on the glass substrate 41 was scanned with a laser light source at an overlap ratio of 93% to be crystallized, whereby a polycrystalline silicon film was obtained. Here, the polycrystalline silicon film on the glass substrate 41 in FIG. 2B was observed by means of the AFM and the SEM. As a result, an optical irradiation hysteresis 52 with a constant interval to form a substantial shape of a lattice 0.2 μm square was observed. Further, a confirmation experiment was carried out with the irradiation conditions of the first pulse laser and those of the second pulse laser as parameters. As a result, it was confirmed that the irradiation hysteresis 52 depended on the laser irradiation conditions, and the substantially lattice shape was formed by setting the energy density of the second pulse laser higher than that of the first pulse laser.

Here, description will be made of a thin film transistor constituted by using the polycrystalline silicon film obtained in accordance with this embodiment with reference to FIG. 4. First, a polycrystalline silicon thin film 103 formed on an insulating substrate 101 was subjected to isolation as it was known. Then, after a gate insulating film 107 and agate electrode 106 were formed, an interlayer insulating film 102 and source/drain electrodes 104 connected to the polycrystalline silicon thin film 103 through contact holes 105 formed in the interlayer insulating film 102 were formed. Accordingly, the thin film transistor was completed. Note that an impurity diffusing step to the polycrystalline silicon thin film 103 is omitted because the step does not directly relate to the present invention and requires complicated description.

Two types of the above-described thin film transistors having the same shapes, each of which had channels in a long side direction and a short side direction on the glass substrate 41, were formed to make a comparison therebetween in terms of a threshold voltage. As a result, the variation in the threshold voltage which depends on the channel direction in the prior art was reduced, and the variation in the threshold voltage of the thin film transistor formed in the glass substrate surface was also significantly improved.

Further, in this embodiment, the dehydrogenization annealing process was performed at 600° C. for 5 hours. However, dehydrogenization of the amorphous silicon film can also be performed by appropriately setting the energy density of the first pulse laser. In this embodiment, it is possible for the dehydrogenizing process to be performed with an energy density of, for example, 180 mj/cm².

### Embodiment 2

A description will be made of a method of crystallizing a semiconductor film in accordance with this embodiment by referring to FIGS. 1A and 1B and FIGS. 2A and 2B, similarly to Embodiment 1. Note that the explanation overlapping that in Embodiment 1 will be appropriately omitted.

As shown in FIGS. 1A and 1B, the glass substrate 41, on which an amorphous silicon film with a thickness of 500 Å has been deposited as a semiconductor film, was scanned by means of the first pulse laser 30 with an energy density having a range in which the semiconductor film is not completely melted, whereby the amorphous silicon film is formed into a film in an incomplete crystalline state in which a part thereof is in an amorphous state. It is sufficient that scanning is performed with a pulse laser with an energy density of, for example, 50 mj/cm² to 250 mj/cm². Next, as shown in FIGS. 2A and 2B, scanning with the second pulse laser 32 was performed with an energy density that enabled sufficient melting of the semiconductor film in an orthogonal direction to the scanning direction of the first pulse laser. Used in Embodiment 2 is, for example, a pulse laser with an energy density of 330 mj/cm² Further, it is possible to completely melt the semiconductor film by using a pulse light source, which had an energy density that ranged approximately from 280 mj/cm² to 400 mj/cm², as the second pulse laser.

As in this embodiment, the conditions with which the semiconductor film was not completely melted were adopted as the irradiation conditions with the first pulse laser, whereby it was observed with the AFM and the SEM that the pulse laser irradiation hysteresis 51 shown in FIG. 1B became clearer in the semiconductor film after scanning with the first pulse laser. Further, the width of the optimum energy density under the irradiation conditions with the second pulse laser, which is shown in FIGS. 2A and 2B, widely ranges from 300 mj/cm² to 400 mj/cm². Therefore, this embodiment provides effective means for reducing variation in crystallization of the semiconductor film with respect to variation in energy density of the laser with time.

When, the same thin film transistor as that in Embodiment 1 was formed on the glass substrate by using the above-described crystallized semiconductor film, variation in a threshold voltage in a substrate surface can be further reduced.

### Embodiment 3

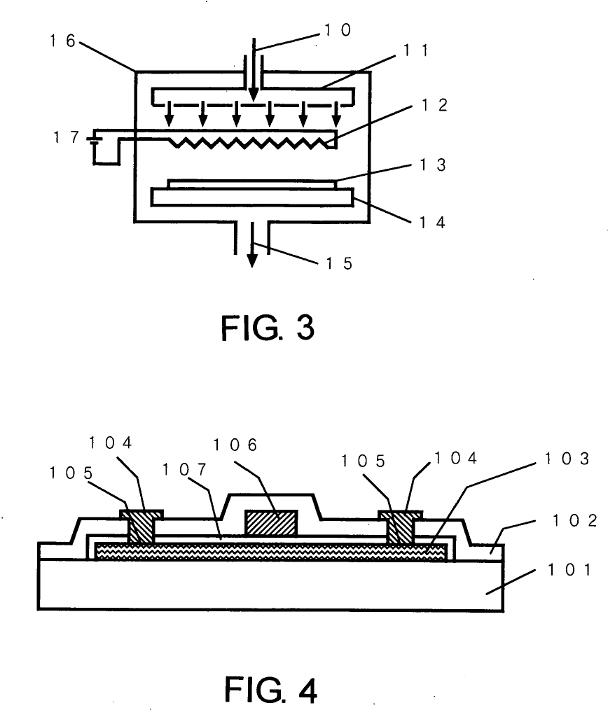

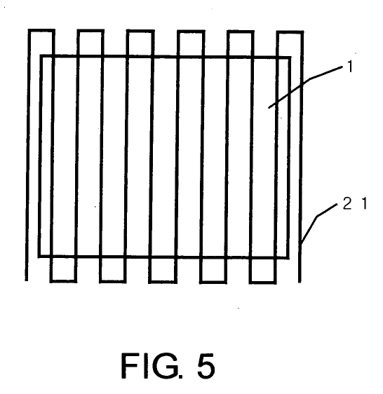

A description of a method of depositing a semiconductor film will be made in accordance with this embodiment with reference to FIG. 3. FIG. 3 schematically shows a case where a semiconductor film is deposited by a catalytic CVD method. A high vacuum is kept in a vacuum chamber 16 through exhaust 15 with a vacuum pump. Further, a material gas 10, whose flow rate is precisely controlled through a massflow controller, is supplied into the vacuum chamber 16 from a shower head 11. Further, a catalytic body 12 for thermally decomposing the material gas 10 is provided at a jetting portion of the shower head 11, and is supplied with electric power for heating the catalytic body 12 from a power source portion 17. In this embodiment, used as the catalytic body 12 was one obtained by processing a 0.5 mm-thick high-purity tungsten wire into a desired shape. A substrate holder 14 for supporting a substrate 13 is provided with a mechanism that can arbitrarily control a temperature not exceeding 600° C. FIG. 5 is a schematic diagram of a shape of the catalytic body 12 used in this embodiment. Used as the catalytic body 12 was a tungsten wire 21 obtained by processing high-purity tungsten (for example, purity of 99.999%) with a diameter of 0.5 mm parallelly and uniformly with respect to a surface of the substrate. Note that the description of a tension mechanism for keeping the shape of the tungsten wire 21 is omitted. Here, the tungsten wire 21 was processed into a desired shape to have a surface area of 0.09 cm² per unit area (1 cm²) (hereinafter, described as 0.09 cm²/cm²) (refer to FIG. 5). Here, the shape of the tungsten wire is not limited to one including a series of concave shapes, which is shown in FIG. 5, and nor is necessarily stroke shaped. That is, it is sufficient that the tungsten wire is processed such that a film deposited on a substrate has an approximately uniform thickness.

An amorphous silicon film was deposited to have a thickness of 500 Å by using SiH₄ and H₂ as material gases by the above-mentioned catalytic CVD method. Deposition conditions in this embodiment were as follows: an ultimate pressure of the vacuum chamber 16 <1.0×10⁻⁶ torr; a surface area per unit area of the catalytic body 12 of about 0.12 cm²/cm²; a surface temperature of the catalytic body 12 of about 180° C.; a temperature of the substrate holder 14 of about 500° C.; the material gases 10 of SiH₄ with a flow rate of 50 sccm and H₂ with a flow rate of 10 sccm; and the distance of 40 mm between the catalytic body 12 and the substrate holder 14. Under the above-mentioned conditions, the 500 Å-thick amorphous silicon film was obtained at a deposition speed of approximately 35 Å/sec. Further, a hydrogen content of the amorphous silicon film obtained under the above-mentioned conditions was 2.5 Atomic %. The above film formation conditions are given as an example. The amorphous silicon film was formed with a hydrogen content of 7.0 Atomic % or less under the conditions of: a surface area per unit area of the catalytic body 12 of about 0.12 cm²/cm² to 0.20 cm²/cm²; a temperature of the catalytic body of 1600° C. to 2100° C.; a temperature of the substrate holder 14 of 200° C. to 600° C.; the distance between the catalytic body 12 and the substrate holder 14 of 30 mm to 200 mm; and a flow rate of SiH₄ of 10 sccm to 100 sccm and a flow rate of H₂ of 10 sccm to 100 sccm. Further, by changing the combination of the conditions, it is possible to form the amorphous silicon film with a hydrogen content that ranges from 0.3 Atomic % to 7.0 Atomic %.

As described above, the amorphous silicon film with a low hydrogen content of 7.0 Atomic % or less was formed as the semiconductor film by using the catalytic CVD method. Subsequently, as in the methods exemplified in Embodiment 1 and Embodiment 2, the amorphous silicon film was crystallized by using the first pulse laser scanning and the second pulse laser scanning, thereby obtaining a polycrystalline silicon film. The amorphous silicon with a low hydrogen content was used as the semiconductor film. Thus, the first pulse laser scanning conditions had a wider optimum condition range, it is possible to perform more stably and crystallization of a more uniform semiconductor film through the second pulse laser scanning. Therefore, there was further reduced variation in a threshold voltage characteristic in a substrate surface and among substrates in a thin film transistor formed by using the crystallized semiconductor film (polycrystalline silicon film).

### Embodiment 4

Further, in Embodiments 1 to 3 described above, the second pulse laser had a line beam having a long side in an orthogonal direction to a traveling direction of scanning, and an overlap ratio of 70% or more and an energy density of 280 mj/cm² to 380 mj/cm² were adopted, thereby making it possible to perform satisfactory crystallization of the semiconductor film. Further, the first pulse laser had a line beam having a long side in an orthogonal direction to a traveling direction of scanning, and an overlap ratio of 70% or more and the difference in energy density between the first pulse laser and the second pulse laser of 150 mj/cm² or less were adopted, thereby making it possible to crystallize the uniform semiconductor film as in Embodiment 1.

### Embodiment 5

A thin film transistor was formed as shown in FIG. 4 by using the semiconductor film as formed above. Further, a liquid crystal display device was manufactured by using a substrate on which the thin film transistor was formed. A transparent pixel electrode made of ITO was provided as the drain electrode of the thin film transistor, an orientating film was then formed thereon, and the orientating film was subjected to an orientation process. As a result, an array substrate was formed. Next, a color filer was provided on a glass substrate, a common electrode made of ITO was formed thereon, and an orientating film was likewise formed thereon to be subjected to an orientation process. As a result, an opposing substrate was formed. The array substrate and the opposing substrate were opposed to each other, liquid crystal was sandwiched in a gap therebetween, and the resultant was held by a sealing agent applied on its circumference. Resultingly, the liquid crystal display device was manufactured.

Although it was manufactured by a simple and easy method, the liquid crystal display device thus manufactured had suppressed variation in transistor characteristic. Therefore, the device showed excellent display uniformity. Examples of display methods of the liquid crystal display device include a TN mode, IPS mode, VA mode, and ECB mode, depending on an initial orientation state of the liquid crystal. In the present invention, the same effects can be obtained irrespective of the liquid crystal display method.

### Embodiment 6

A thin film transistor was formed as shown in FIG. 4 by using the semiconductor film as formed above. Further, an EL display device was manufactured by using a substrate on which the thin film transistor was formed. A transparent pixel electrode made of ITO was provided to the drain electrode of the thin film transistor, and a hole injecting layer made of copper phthalocyanine or the like was then formed thereon by evaporation. Similarly, a hole transporting layer made of α-NPD and a light emitting layer made of Alq₃ were laminated thereon by evaporation. Next, a cathode made of LiF and Al was formed thereon also by evaporation, and a sealing substrate for protecting elements was bonded thereon with the use of a sealing agent. As a result, an organic EL display device was manufactured.

Although it was manufactured by a simple and easy method, the organic EL display device thus manufactured had suppressed variation in a transistor characteristic. Therefore, the device showed excellent display uniformity.

Further, an example of driving with one thin film transistor was shown in this embodiment. However, there is a case where the organic EL display device is used in a current drive, and in this case, a constant current circuit may be composed of plural transistors to form a display device. In this case, it goes without saying that uniformity of the plural transistors constituting the circuit is required, and high uniformity of the transistor shown in the present invention brings about high effects.

As described above, according to the method of crystallizing a semiconductor film, the semiconductor film can be uniformly crystallized. Therefore, there is an effect that the thin film transistor liquid crystal display or the organic EL display can be produced with a high yield by using the uniformly crystallized semiconductor film without deterioration of the display quality.

As a result, the silicon film for the thin film transistor used for the liquid crystal display, the organic EL display, or the like can be uniformly crystallized, which enables the reduction of variation in the characteristics of the thin film transistor in the substrate surface. Accordingly, stable manufacturing of a display can be realized without deterioration of the display quality.

What is claimed is:

1. A method of crystallizing a semiconductor film in which a semiconductor film is formed into a polycrystalline semiconductor film through scanning with pulse lasers, comprising the steps of:
scanning a semiconductor film with a first pulse laser; and
scanning the semiconductor film with a second pulse laser in a substantially orthogonal direction to a scanning direction of the first pulse laser, wherein an energy density of the first pulse laser is lower than an energy density of the second pulse laser.

2. A method of crystallizing a semiconductor film according to claim 1, wherein the first pulse laser has an energy density that does not completely melt the semiconductor film.

3. A method of crystallizing a semiconductor film according to claim 1, wherein the semiconductor film is formed by a catalytic CVD method.

4. A method of crystallizing a semiconductor film according to claim 1, wherein, in the first step, dehydrogenization of the semiconductor film is performed through scanning with the first pulse laser.

5. A method of crystallizing a semiconductor film according to claim 1, wherein the semiconductor film is composed of an amorphous silicon thin film with a hydrogen content of 7 Atomic % or less.

6. A method of crystallizing a semiconductor film according to claim 1, wherein:
the second pulse laser provides a line beam having a long side in a perpendicular direction to a scanning traveling direction of the second pulse laser; and
irradiation is performed with an overlap ratio of 70% or more and a pulse energy per time, which ranges from 280 mj/cm² to 380 mj/cm².

7. A method of crystallizing a semiconductor film according to claim 6, wherein:
the first pulse laser provides a line beam having a long side in a perpendicular direction to a scanning traveling direction of the first pulse laser; and
irradiation is performed with an overlap ratio of 70% or more and a difference in energy between the first pulse laser and the second pulse laser is 150 mj/cm² or less.

8. A method of manufacturing a display device, comprising the steps of:
scanning a semiconductor film formed on a first substrate with a first pulse laser;
scanning the semiconductor film with a second pulse laser in a substantially orthogonal direction to a scanning direction of the first pulse laser;
forming a thin film transistor with the use of the semiconductor film; and
forming a display element with the use of the first substrate, wherein an energy density of the first pulse laser is lower than an energy density of the second pulse laser.
